(19) United States
(12) Patent Application Publication
(10) Pub. No.: US 2019/0252950 A1
(43) Pub. Date: Aug. 15, 2019

(54) MOTOR POSITION SENSOR DESIGN

(71) Applicant: Integrated Device Technology, Inc., San Jose, CA (US)

(72) Inventor: Andreas Buchinger, Waidhofen/Ybbs (AT)

(21) Appl. No.: 16/276,549

(22) Filed: Feb. 14, 2019

Related U.S. Application Data
(60) Provisional application No. 62/631,370, filed on Feb. 15, 2018.

(51) Int. Cl. H02K 11/225; H05K 1/16; H02K 11/00; H02K 11/01; H02K 11/33

(52) U.S. Cl. CPC H02K 11/225; H05K 1/165; H02K 11/33; H02K 11/01; H02K 11/0094

(57) ABSTRACT

In some embodiments, a position sensing system for an electronic motor includes a board having a transmitter and inductive sensors; a housing in which the board is mounted, the housing including an opening; and a conductive shield positioned to cause uniformity in the electromagnetic fields from the transmit and the receive coils. A method of providing a position sensing system includes mounting a board with inductive sensing in a housing, the housing including an opening that allows electrical connection to the board; shielding the board to provide uniformity in the electromagnetic fields at transmit and receive coils on the board; and positioning a target relative to the board.

### RELATED APPLICATIONS

This disclosure claims priority to U.S. Provisional Application 62/631,370, filed on Feb. 15, 2018, which is herein incorporated by reference in its entirety.

### TECHNICAL FIELD

Embodiments of the present invention are related to motor position sensing.

### DISCUSSION OF RELATED ART

Position sensors are used in various settings for measuring the position of one component with respect to another. Inductive position sensors can be used in automotive, industrial and consumer applications for absolute rotary and linear motion sensing. In many inductive positioning sensing systems, a transmit coil is provides a magnetic field that is received by receiver coils. Further, eddy currents are induced in a metallic target that is sliding or rotating above the set of coils. Receiver coils receive the magnetic field generated by the transmit coil, which is interfered with by the eddy currents, and provide signals to a processor. The signals from the receiver coils are used to determine the position of the metallic target above the set of coils. The processor, transmitter, and receiver coils may be formed on a printed circuit board (PCB).

However, many of these systems exhibit inaccuracies for many reasons. For example, the electromagnetic field generated by the transmitter, and the resulting fields generated in the metallic target, may be non-uniform, the connections of wires may result in non-uniformity, the air-gap (AG) between the metallic target and the coils mounted on the PCB may be non-uniform, the amplitudes between multiple signal coils may be offset, there may be mismatches between the multiple signal coils, there may be different coupling effects between the metallic target and each of the multiple signal coils, and other factors may result in inaccurate results.

Consequently, there is a need for more accurate and linear position sensing systems.

### SUMMARY

In some embodiments, a position sensing system for an electronic motor includes a board having a transmitter and inductive sensors; a housing in which the board is mounted, the housing including an opening; and a conductive shield positioned so as to cause uniformity in the electromagnetic fields from the transmit and the receive coils.

A method of providing a position sensing system includes mounting a board with inductive sensing in a housing, the housing including an opening that allows electrical connection to the board; shielding the board to provide uniformity in the electromagnetic fields at transmit and receive coils on the board; and positioning a target relative to the board.

These and other embodiments are discussed further below with respect to the following figures.

### BRIEF DESCRIPTION OF THE FIGURES

FIG. 1A illustrates a position sensing system without a housing incorporated in a testing system.

FIG. 1B illustrates a block diagram of the testing system illustrated in FIG. 1A.

FIGS. 1C and 1D illustrate a position sensing system incorporated with a motor device.

FIGS. 2A and 2B illustrate simulated and measured errors in a position system measured as illustrated in FIG. 1.

FIGS. 3A and 3B illustrate a position sensing system with a housing.

FIG. 3C illustrates the relative error measured using the position sensing system illustrated in FIGS. 3A and 3B.

FIG. 4 illustrates a position sensing system according to some embodiments of the present invention.

FIGS. 5A and 5B illustrate a position sensing system according to other embodiments of the invention and relative error according to some embodiments, respectively.

These and other aspects of the present invention are further discussed below.

### DETAILED DESCRIPTION

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description illustrates inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention.

Embodiments of the present invention allow for improved performance of an inductive position sensor when asymmetric metallic or conducting housings are in close proximity to the sensor module. In some embodiments, the sensor module can be mounted in a housing. In accordance with some embodiments, a conductive, for example copper, foil is positioned to provide a symmetric environment for the module. As in many embodiments, the sensor module can include transmit coils, sensor coils, and an integrated circuit processor positioned on a printed circuit board mounted within the housing. The target is positioned over the sensor module.

The conducting foil allows for electrically closing loops in the housing so that the housing appears to be symmetrical to the sensor module. This enables eddie currents to be induced in the conducting foil around the entire circumference of the housing, which has a symmetrical influence to the whole sensor setup.

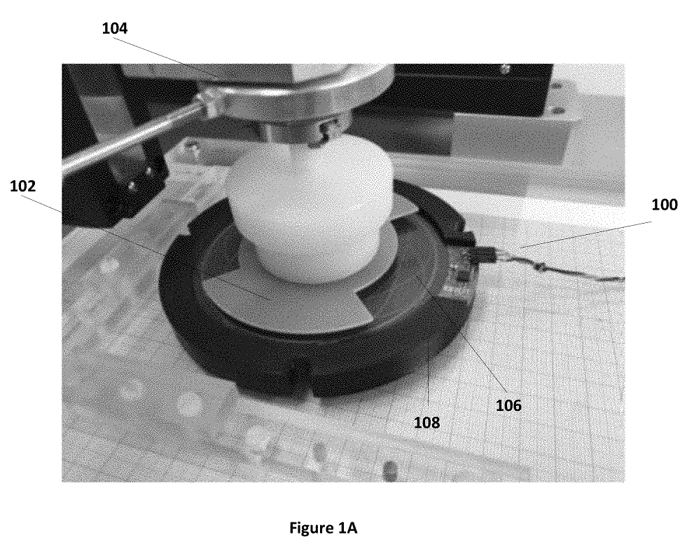

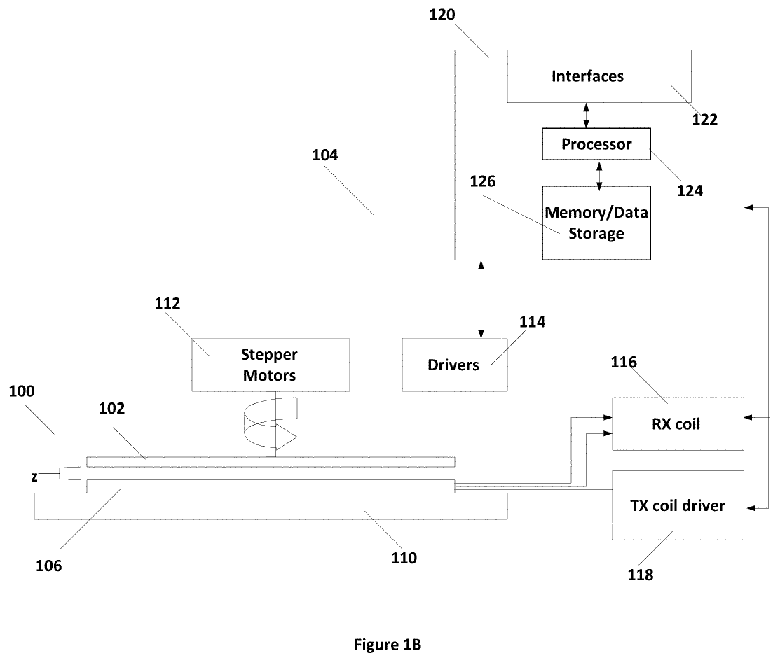

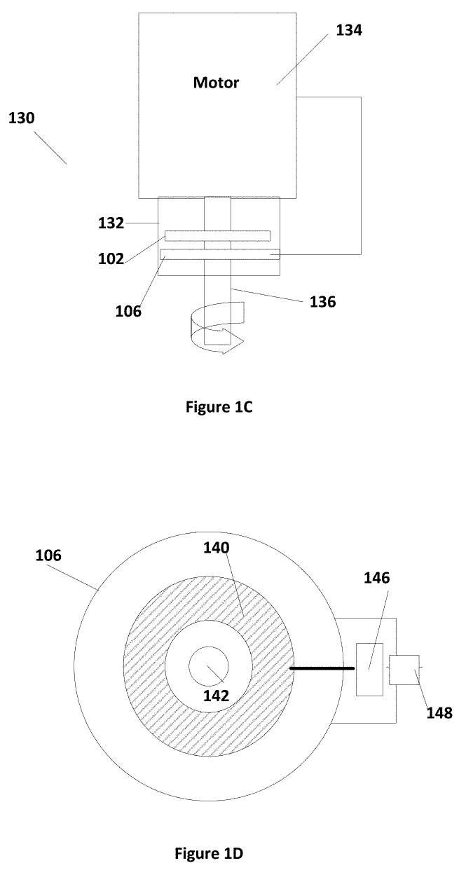

FIG. 1A illustrates a position sensing system 100 in a testing system 104. Testing system 104 is configured to controllably rotate a target 102 over position sensing system 100 and compare the measured position from position sensing system 100 with the actual position of target 102. As is illustrated in FIG. 1, position sensing system 100 includes a coil board 106, which may be a printed circuit board (PCB), on which position sensing coils and transmit coils are printed. In some cases, circuitry for driving the transmit coil and receiving signals from the sensing coils can be provided. A ring 108 can be used to hold printed circuit board 106 onto a base 110 (shown in FIG. 1B).

FIG. 1B illustrates a block diagram of a position sensing system 100 in a testing system 104 as illustrated in FIG. 1A. As is illustrated in FIG. 1B, position sensing system 100 includes a coil board 106, which is positioned on a base 110 of testing system 104. As shown in FIG. 1A, a ring 108 (not shown in FIG. 1B) can be used to hold board 106 onto base 110. Position sensing system 100 further includes a target 102, which is a conductive structure as illustrated in FIG. 1A. The conductor on target 102 can, for example, be mounted on a printed circuit board itself. Board 106 includes a transmit coil as well as receive coils, typically a cosine coil and a sine coil, for detecting the position of target 102 relative to board 106. As illustrated in FIGS. 1A and 1B, position sensor 100 is a circular position and senses the angular position of target 102 relative to the sensor coils of board 106. Transmit coils on board 106 can be driven by a driver 118. Receiver signals, for example signals from a sine receive coil and a cosine receive coil, are received by coil receive circuit 116. In some embodiments, circuit 116 and driver 118 can be included on board 106 and, in particular, be included in a sensor integrated circuit (IC) mounted on board 106. As shown in FIG. 1B, the sensor IC is coupled to a controller 120 of test device 104, or in actual application to a motor control circuit Driver 118 receives digital signals from a controller 120 while circuit 116 provides digitized signals to controller 120.

As is illustrated in FIG. 1B, stepper motors 112 are coupled to target 102. Stepper motors 112 rotate target 102 in a precise fashion. In some embodiments, stepper motors 112 may also be able to adjust the height z above board 106. In examples depicted here, the position z is already designed into position sensor 100 as position sensor 100 is constructed and packaged.

Stepping motors 112 is controlled by motor drivers 114, which receives digital signals from controller 120. Accordingly, the rotational position of target 102 relative to board 106 is precisely known by controller 120 through the position of stepper motors 112.

Controller 120 is coupled to provide control signals to drivers 114 and driver 118 and receive signals from coil 116. Controller 120 can, for example, include a processor 124 coupled to a memory and data storage 126. Processor 124 can be an microprocessor or microcomputer capable of executing instructions for controlling stepper motors 112 and receiving and analyzing data from the circuit 116. Memory and data storage 126 can include volatile and nonvolatile memory as well as hard storage for holding data and programming instructions executed by processor 124. Further, processor 124 is coupled to interfaces 122, which can include user interfaces such as user input device, display screens, and the such. Interfaces 122 also includes interfaces to drivers 114, coil circuit 116, and driver 118 as well as standard interfaces such as USB, I2C, or other interfaces. Controller 120, in some embodiments, can be an interfaceable computer such as a laptop or other device.

As such, controller 120 precisely controls the position of target 102 relative to board 106. Also, from the signals received from coil circuit 116, controller 120 can calculate the position of target 102 according to position sensor 100. These two values can be compared to arrive at an error in the position as indicated by position sensor 100 relative to the actual position as is determined by stepper motors 112.

FIG. 1C illustrates a position sensor 130 in actual operation, as opposed to being positioned in a testing device as illustrated in FIGS. 1A and 1B. As illustrated in FIG. 1C, position sensor 130 includes a sensor board 102 mounted in a housing 132. In some embodiments, sensor board 102 can be over-molded or mounted in a plastic enclosure. Sensor board 102 is included in a housing 132. Target 102 can be mounted on a shaft 136 of a motor 134. The shaft 136 extends through position sensor 130. The signals from the coils mounted on sensor board 102 are coupled into motor 134. Motor 134 can be, for example, an electric motor, a water pump, a transmission system, or other rotational device.

FIG. 1D further illustrates an example sensor board 106. Sensor board 106 includes inductive sensors 140, which can include transmit coils and receiver coils (sine and cosine coils). In some embodiments, inductive sensors 140 can be other induction sensors such. Further, where inductive sensors 140 include coils, there may be any number of transmit coils and receive coils. Inductive sensors 140 can be coupled to a sensor integrated circuit 146, which can include a processor to receive signals from the receive coils (RX coil 116), a drive the transmit coil (driver 118). Signals from sensor IC 146 can be coupled through a connector 148 to provide signals to other controllers (e.g., controller 120 illustrated in FIG. 1B or controllers in motor 134 illustrated in FIG. 1C.

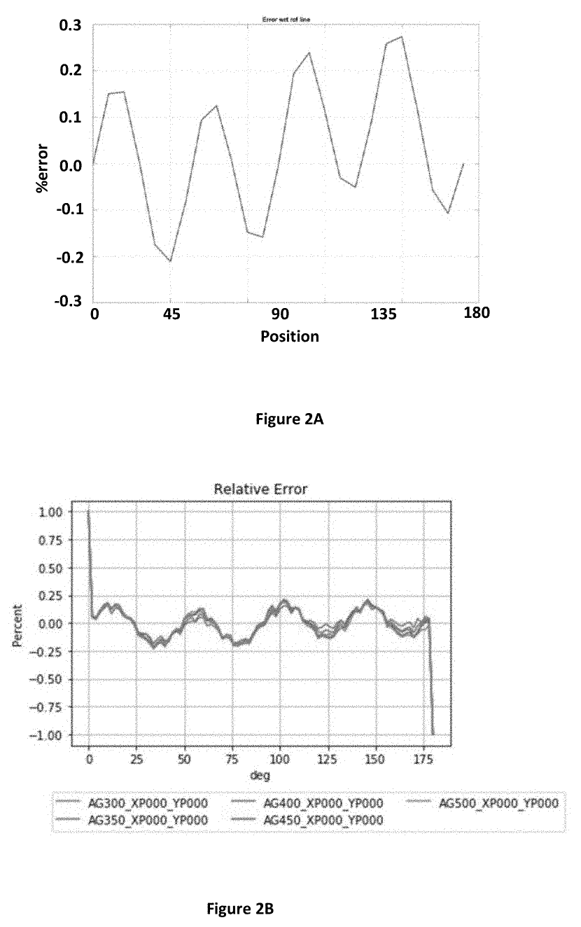

FIGS. 2A and 2B illustrate testing results with the position sensing system illustrated in FIG. 1A, which as illustrated does not include a housing for position sensor 100. Target 102 is shown as illustrated in FIG. 1A and, in this example, is a steel target with an OD of about 95 mm. In general, target 102 can be formed of any conductor, for example steel, copper, or other conducting material. No compensation was used. Without target 102 in place, the measured offsets from the signals from sine and cosine coils in board 106 was about 0 on both channels. FIG. 2A illustrates a simulation of the expected error from position sensor 100. FIG. 2B illustrates the measured errors from a number of examples of position sensor 100 measured by testing system 104 as described above. As is illustrated in FIGS. 2A and 2B, the expected error from position sensor 100 is about ±0.25%, which is both the measured and the simulated prediction. As is illustrated in FIGS. 2A and 2B, the simulated and actually measured relative error match and illustrate that the printed circuit board and coil design is functioning well. However, this low error rate is not upheld when position sensor 100 is packaged in a housing. The housing interferes with the functionality of position sensor 100 and results in much higher error rates than those that would be expected according to FIGS. 2A and 2B above.

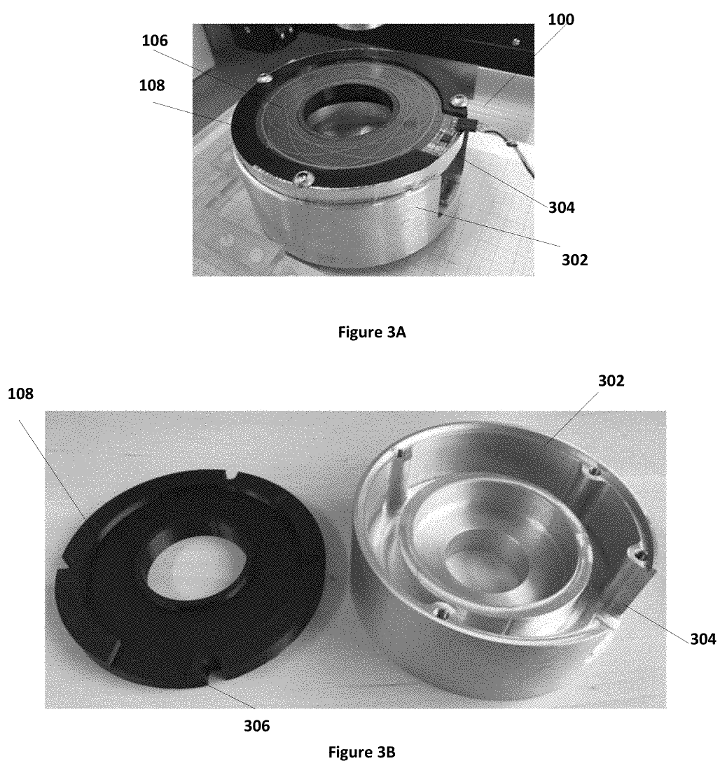

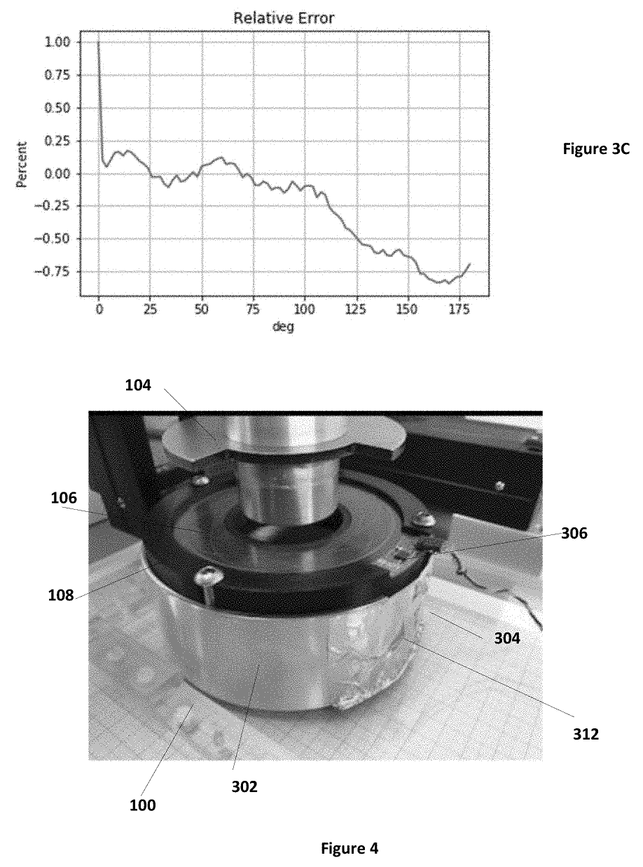

FIGS. 3A and 3B illustrate positioning system 100 packaged in a housing 302. As is illustrated in FIG. 3A, board 106 of positioning system 100 is packaged in a housing 302 with an asymmetric shape that includes an opening 304. As is illustrated in FIG. 3B, ring 108 also includes an opening 306, which aligns with opening 304 of housing 302 to provide access to circuits (e.g., driver 118 and circuit 116) or connections to coils that are on board 106.

FIG. 3C illustrates measurement of the error in positioning system 100 packed in housing 302 as illustrated in FIG. 3A. Again, target 102 is a steel target with OD of 95 mm. There is no compensation applied to the integrated circuit for driving transmitter coils or receive coils. The offset measured without target 102 in place is +150 and −80 LSBs. As is illustrated in FIG. 3C, the relative error is +/−0.6%. Consequently, it is apparent that housing 304 is influencing the offset due to its asymmetric shape. Cut out 304 in the other ring is introducing unsymmetrical behavior, which is increasing the error in measuring positions by a about a factor of 3.

FIG. 4 illustrates an embodiment of the present invention placed in testing system 104 without the presence of target 102 in order to measure offsets. As is illustrated, opening 304 is covered by a conducting copper foil 312. Covering the cut out of the housing with conducting material shows a big improvement in the offset measurement, which is performed without the presence of target 102. One channel was reduced to about 0 while the second channel continued to show a residual offset of about 50 LSBs.

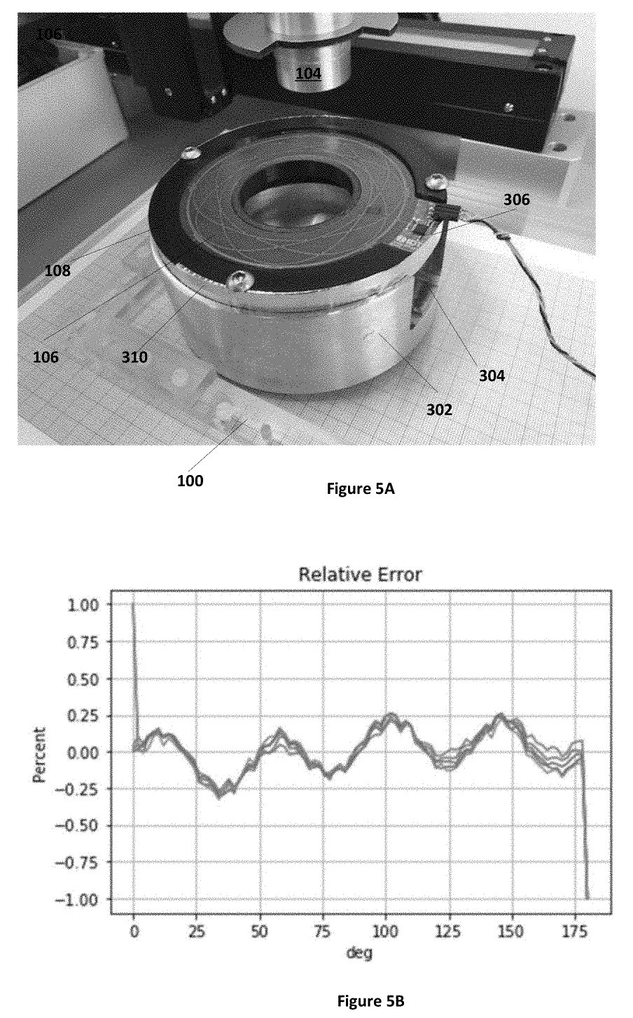

FIG. 5A illustrates a positioning system 100 according to some embodiments with a metallic shield 310 positioned around ring 106. Positioning system 100 is positioned relative to testing system 104. Target 102 is not shown in FIG. 5A. However, measurement was performed with the housing 302. Target 102 was a real steel target with OD 95 mm. No IC compensation was used. Metallic shield 310 is a shielding ring formed of copper foil on the outside of plastic ring 108. Metallic shield 310 forms a more symmetrical environment for board 106.

The introduction of metallic shield 310 helps reduce the residual offset back to the original level of about 0 on both channels. As illustrated in FIG. 5B, the error measurement that was measured with metallic shield 310 was again reduced to +/−0.25%, which was the result obtained absent housing 302. Consequently, applying metallic shield 310 is highly beneficial for operation of position sensing system 100.

In some embodiments, sensor board 106 can be directly mounted into a housing (e.g. a housing with an opening) and electrical connections for a shield can be a printed surface loop on board 106. The electrically connected ring can be integrated into a plastic housing or the housing itself be partially conductive.

The above detailed description is provided to illustrate specific embodiments of the present invention and is not intended to be limiting. Numerous variations and modifications within the scope of the present invention are possible. The present invention is set forth in the following claims.

What is claimed is:

1. A position sensing system, comprising
a board having a transmitter and inductive sensors;
a housing in which the board is mounted, the housing including an opening; and
a conductive shield positioned so as to cause uniformity in the electromagnetic fields from the transmit and the receive coils.

2. The position sensing system of claim 1, further including a ring that holds the board to the housing, wherein the conductive shield is positioned around the shield.

3. The position sensing system of claim 2, wherein the ring includes a ring opening positioned relative to the opening in the housing.

4. The position sensing system of claim 1, further including a conductive foil positioned over the opening in the housing.

5. The position sensing system of claim 1, wherein the percent error of the position sensing system is less than ±0.25.

6. The position sensing system of claim 2, wherein the conductive shield is a copper foil.

7. The position sensing system of claim 4 wherein the conductive foil is a copper foil.

8. A method of providing a position sensing system, comprising:
mounting a board with inductive sensing in a housing, the housing including an opening that allows electrical connection to the board;
shielding the board to provide uniformity in the electromagnetic fields at transmit and receive coils on the board; and
positioning a target relative to the board.

9. The method of claim 8, wherein mounting the board includes holding the board in the housing with a ring, and wherein shielding the board includes positioning a conductive shield around the ring.

10. The method of claim 9, wherein the ring includes a ring opening positioned relative to the opening in the housing.

11. The method of claim 8, wherein shielding the board includes positioning a conductive foil over the opening in the housing.

12. The method of claim 8, wherein the percent error of the position sensing system is less than ±0.25.

13. The method of claim 9, wherein the conductive shield is a copper foil.

14. The position sensing system of claim 11 wherein the conductive foil is a copper foil.

15. A position sensor, comprising:
a means for mounting a board with inductive sensing onto a housing; and
a means for shielding the board to provide uniformity in the electromagnetic fields at transmit and receive coils on the board.
